(19) United States
(12) Patent Application Publication
(10) Pub. No.: US 2026/0123005 A1
(43) Pub. Date: Apr. 30, 2026

(54) TRANSISTOR WITH FIELD PLATE

(71) Applicant: GlobalFoundries Singapore Pte. Ltd., Singapore (SG)

(72) Inventors: Bong Woong Mun, Singapore (SG); Aloysius Priartanto Herlambang, Singapore (SG)

(21) Appl. No.: 18/933,323

(22) Filed: Oct. 31, 2024

(51) Int. Cl. H01L 29/40; H01L 29/66; H01L 29/78

(52) U.S. Cl. CPC H10D 64/112; H10D 30/0281; H10D 30/65

(57) ABSTRACT

The present disclosure relates to semiconductor structures and, more particularly, to a transistor with a field plate and methods of manufacture. The structure includes: a gate structure on a semiconductor substrate; a source region on a first side of the gate structure; a drain region on a second side of the gate structure; and a field plate extending over the gate structure from the source region to the drain region, the field plate including at least one via structure extending toward the drain region.

### BACKGROUND

The present disclosure relates to semiconductor structures and, more particularly, to a transistor with a field plate and methods of manufacture.

A laterally-diffused metal-oxide semiconductor (LDMOS) is a planar double-diffused MOSFET (metal-oxide-semiconductor field-effect transistor) used in amplifiers, including microwave power amplifiers, RF power amplifiers and audio power amplifiers. Silicon-based RF LDMOS devices are widely used in RF power amplifiers in mobile networks for cellular voice and data traffic. The LDMOS RF power amplifiers are also used in base-stations as the requirement is for high output power with a corresponding increased drain to source breakdown voltage.

### SUMMARY

In an aspect of the disclosure, a structure comprises: a gate structure on a semiconductor substrate; a source region on a first side of the gate structure; a drain region on a second side of the gate structure; and a field plate extending over the gate structure from the source region to the drain region, the field plate comprising at least one via structure extending toward the drain region.

In an aspect of the disclosure, a structure comprises: a gate structure; a source region on a first side of the gate structure; a drain region on a second side of the gate structure; a first field plate extending over the gate structure and connecting to the source region; a second field plate over the gate structure and the first field plate, the second field plate connecting to the source region and extending to the drain region, the second field plate comprising at least one via structure extending toward the drain region; and a spacer between the at least one via structure and the drain region.

In an aspect of the disclosure, a method comprises: forming a gate structure on a semiconductor substrate; forming a source region on a first side of the gate structure; forming a drain region on a second side of the gate structure; and forming a field plate extending over the gate structure from the source region to the drain region, the field plate comprising at least one via structure extending toward the drain region.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a device and respective fabrication processes in accordance with aspects of the present disclosure.

FIGS. 2-5 show alternative devices in accordance with additional aspects of the present disclosure.

### DETAILED DESCRIPTION

The present disclosure relates to semiconductor structures and, more particularly, to a transistor with a field plate and methods of manufacture. More specifically, the transistor may be a laterally diffused metal oxide semiconductor (LDMOS). In embodiments, the field plate extends over the gate structure and the drain side of the device, e.g., over the drift region, with downwardly extending via structures over the drain side of the device, e.g., drift region. A space or gap may be provided between the drift region and the downwardly extending via structures. Advantageously, the field plate extension helps to deplete the drift region, reduce surface electric field, and increase breakdown voltage.

By way of example, the LDMOS includes a gate structure on a semiconductor substrate. The gate structure includes a source region and a drain region, e.g., a drift region. A field plate extends longitudinally over the gate structure with at least one via structure extending downwardly over the drain region of the device. The at least one via structure may be composed of a conductive (e.g., metal) material which is perpendicular to the longitudinal field plate. An interconnect structure extends from the field plate and contacts the source region of the device. In this way, the field plate is connected to the source region, extends over the gate structure and includes one or more downwardly extending via structures over the drift region. The one or more via structure may also extend over the drain region on different wiring levels, with the via structures having different spacing from the drain region and/or different dimensions.

The structures of the present disclosure can be manufactured in a number of ways using a number of different tools. In general, though, the methodologies and tools are used to form structures with dimensions in the micrometer and nanometer scale. The methodologies, i.e., technologies, employed to manufacture the structures of the present disclosure have been adopted from integrated circuit (IC) technology. For example, the structures are built on wafers and are realized in films of material patterned by photolithographic processes on the top of a wafer. In particular, the fabrication of the structures uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

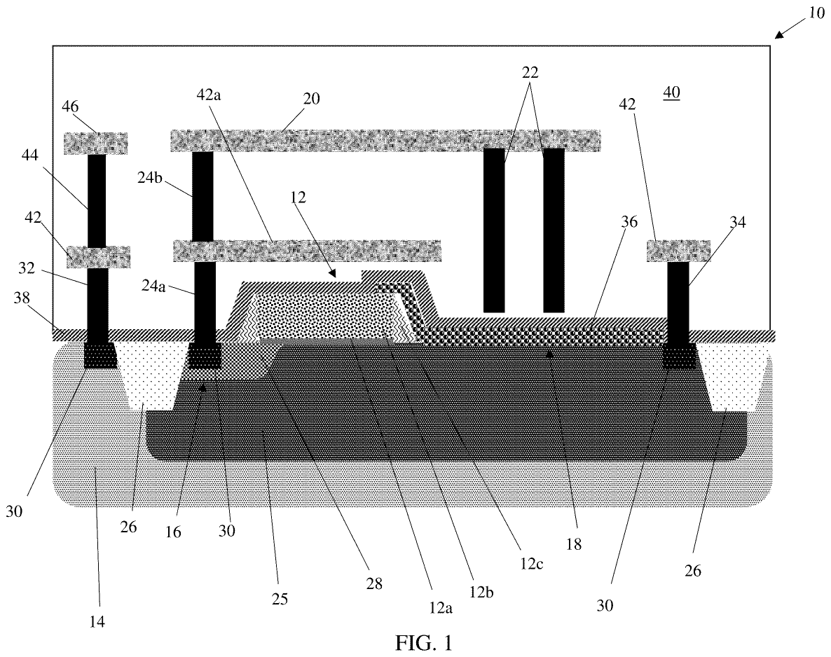

FIG. 1 shows a device and respective fabrication processes in accordance with aspects of the present disclosure. More particularly, the device 10 includes a gate structure 12 over a semiconductor substrate 14. A source region 16 is provided on a first side of the gate structure 12 and a drain region 18, e.g., drift region, is provided on a second side of the gate structure 12. A field plate 20 extends over the gate structure 12, extending from the source region 16 to the drift region 18. The field plate 20 includes one or more via structures 22 extending toward the semiconductor substrate 14 and over the drift region 18. The field plate 20 may be connected to the source region 16 by interconnect structures (vias) 24a, 24b, provided at different wiring levels. The one or more via structures 22 may be fabricated with the same processes as the interconnect structure 24a and/or interconnect structure 24b.

More specifically, the device 10 is fabricated on a semiconductor substrate 14. The semiconductor substrate 14 may be composed of any suitable material including, but not limited to, Si, SiGe, SiGeC, SiC, GaAs, InAs, InP, and other III/V or II/VI compound semiconductors. In embodiments, the semiconductor substrate 14 may be a p-type semiconductor substrate with a suitable single crystallographic orientation (e.g., a (100), (110), (111), or (001) crystallographic orientation).

The semiconductor substrate 14 may be a bulk substrate or semiconductor-on-insulator (SOI) technology. In the SOI technology, a handle substrate and the semiconductor substrate 14 may include the same semiconductor material as noted herein. As is known in the art, the handle substrate provides mechanical support to a buried insulator layer and the top semiconductor layer, e.g., semiconductor substrate 14. The buried insulator layer may include a dielectric material such as silicon dioxide, silicon nitride, silicon oxynitride, boron nitride or a combination thereof. In one preferred embodiment, the buried insulator layer may be a buried oxide layer formed by a deposition process, such as chemical vapor deposition (CVD), plasma enhanced chemical vapor deposition CVD (PECVD) or physical vapor deposition (PVD), or a thermal growth process as is known in the art such that no further explanation is required herein for a complete understanding of the present disclosure.

Still referring to FIG. 1, an n-well 25 may be provided in the semiconductor substrate 14. The n-well 25 may be formed by an ion implantation process. For example, a patterned implantation mask may be used to define selected areas exposed for the implantation, e.g., n-well 25. The implantation mask may include a layer of a light-sensitive material, such as an organic photoresist, applied by a spin coating process, pre-baked, exposed to light projected through a photomask, baked after exposure, and developed with a chemical developer. The implantation mask has a thickness and stopping power sufficient to block the masked area against receiving a dose of the implanted ions. The n-well 25 is doped with n-type dopants, e.g., Arsenic (As), Phosphorus (P) and Antimony (Sb), among other suitable examples.

The n-well 25 may be isolated from other structures by shallow trench isolation structures 26. For example, the shallow trench isolation structures 26 may be provided about, e.g., surrounding, the n-well 25. The shallow trench isolation structures 26 can be formed by conventional lithography, etching and deposition methods known to those of skill in the art. For example, a resist formed over the semiconductor substrate 14 is exposed to energy (light) and developed utilizing a conventional resist developer to form a pattern (opening(s)). An etching process with a selective chemistry, e.g., reactive ion etching (RIE), will be used to transfer the pattern to form one or more trenches in the semiconductor substrate 14 through the openings of the resist. Following the resist removal by a conventional oxygen ashing process or other known stripants, insulator material, e.g., oxide, can be deposited by any conventional deposition processes, e.g., chemical vapor deposition (CVD) processes. Any residual material on the surface of the semiconductor substrate 14 can be removed by conventional chemical mechanical polishing (CMP) processes.

The source region 16 may include a diffusion region 28. In embodiments, the diffusion region 28 may be a p-type diffusion, e.g., boron, formed by an ion implantation process as already described herein. In embodiments, the diffusion region 28 may extend within and outside of the n-well 25, with the diffusion region 28 within the n-well 25 forming part of the source region 16. The shallow trench isolation structure 26 may be used to separate portions of the diffusion region 28, e.g., within and outside of the n-well 25. The source region 16 and the drain region 18 may also include a p-diffusion region 30. The p-diffusion region 30 may be formed by an ion implantation process with a higher dopant concentration than the diffusion region 28.

FIG. 1 further shows the gate structure 12 over the semiconductor substrate 14, positioned between the source region 16 and the drain region 18. In embodiments, the gate structure 12 includes a gate dielectric material 12a and a gate electrode 12b. In embodiments, the gate dielectric material 12a may be a high-k dielectric material such as a hafnium based material. The gate electrode material 12 may be a polysilicon material. Sidewall spacers 12c are formed on the sidewalls on the gate structure 12, e.g., gate dielectric material 12 and gate electrode 12b. The sidewall spacers 12c may be oxide and/or nitride material.

Although not critical to the understanding of the present disclosure, the gate structure 12 can be fabricated using conventional CMOS processes or replacement gate processes. In the standard CMOS processing, the gate dielectric 12a and polysilicon material 12b are formed, e.g., deposited, onto the semiconductor substrate 14, followed a patterning process. An insulator material such as nitride or oxide can be deposited on the patterned materials, followed by an anisotropic etching process to form the sidewall structures 12c. The gate dielectric 12a may be deposited by a conventional CVD process or, alternatively, an atomic layer deposition (ALD) or plasma-enhanced CVD (PECVD) as other examples. The material of the sidewall structures 12c may be deposited by a CVD process, with the sidewall structures 12c being patterned by an anisotropic etching process as is known in the art.

A sacrificial material 36 may be formed over the drift region 18 and partially on the gate structure 12 (on the drain side of the gate structure 12). In embodiments, the sacrificial material 36 may be a sacrificial oxide material that is deposited by a conventional deposition method, e.g., CVD, followed by a patterning process, e.g., lithography and etching processes. The sacrificial material 36 may prevent formation of silicide contacts during a silicide process. An etch stop material 38 may be formed over the sacrificial material 36, gate structure 12 and exposed portions of the semiconductor substrate 14. In embodiments, the etch stop material 38 may be a nitride material.

Prior to forming of the interconnect structures, e.g., 32, 34, 24a, (and contact to the gate structure 12), silicide contacts may be formed on the diffusion regions 30, e.g., source and drain regions. The silicide contacts may also be formed on the gate structure 14. As should be understood by those of skill in the art, the silicide process begins with deposition of a thin transition metal layer, e.g., nickel, cobalt or titanium, over fully formed and patterned semiconductor devices (e.g., doped or ion implanted source and drain regions and gate structure). After deposition of the material, the structure is heated allowing the transition metal to react with exposed silicon (or other semiconductor material as described herein) in the active regions of the semiconductor device (e.g., source and drain regions and gate structure) forming a low-resistance transition metal silicide. Following the reaction, any remaining transition metal is removed by chemical etching, leaving silicide contacts in the active regions of the device.

The interconnect structures 24a, 32, 34 (and, in one embodiment, the lower portion of the via structures 22) may be formed by conventional patterning and deposition processes. For example, a trench may be formed in interlevel dielectric material 40, e.g., oxide and/or nitride, and the etch stop layer 38, followed by deposition of conductive material. The trench may be formed by conventional lithography and etching (RIE) processes. The conductive material of the interconnect structures 24a, 32, 34 (and the lower portion of the via structures 22) may be deposited in the trenches by conventional CVD processes, using conventional metals or metal alloys, e.g., aluminum, copper or tungsten, with a liner material, e.g., TaN, TiN, etc.

Metal wiring structures 42a, 42 may be formed to the interconnect structures 24a, 32, 34 using conventional deposition and patterning processes as already described herein. The wiring structures 42a, 42 may be formed from any conventional metal or metal alloy as is known in the art, e.g., aluminum, copper, etc. It should be understood by those of skill in the art that the metal wiring structure 42a may be a field plate on a first wiring level, which extends over the gate structure 12 and partially over the drift region 18.

As further shown in FIG. 1, additional vias 44, 24b and the via structures 22 (or, in one embodiment, an upper portion of the via structures 22 when the lower portions have been previously formed) may be formed in a similar manner to the interconnect structures 24a, 32, 34. The additional vias 44, 24b are connected to (e.g., in contact with) the wiring structures 42, 42a and wiring structures 20, 46. The wiring structure 20 is also in contact with the upper portion of the via structures 22, which extends downward towards the drift region 18. The wiring structures 20, 46 may be formed from any conventional metal or metal alloy as is known in the art, e.g., aluminum, copper, etc.

In embodiments, the wiring structure 20 is a field plate on an upper wiring level of the device 10, with the via structures 22 extending from the wiring structure 20 to over the drift region 18, e.g., drain region. As shown in FIG. 1, the via structures 22 will extend over and are spaced apart from the drift region 18. For example, in embodiments, the via structures 22 may be above the etch stop layer 38. The via structures 22 may also extend partially into etch stop layer 38, without contacting the drift region 18. The wiring structures 20, 42, 42a, 46 may be formed from any conventional metal or metal alloy as is known in the art, e.g., aluminum, copper, etc.

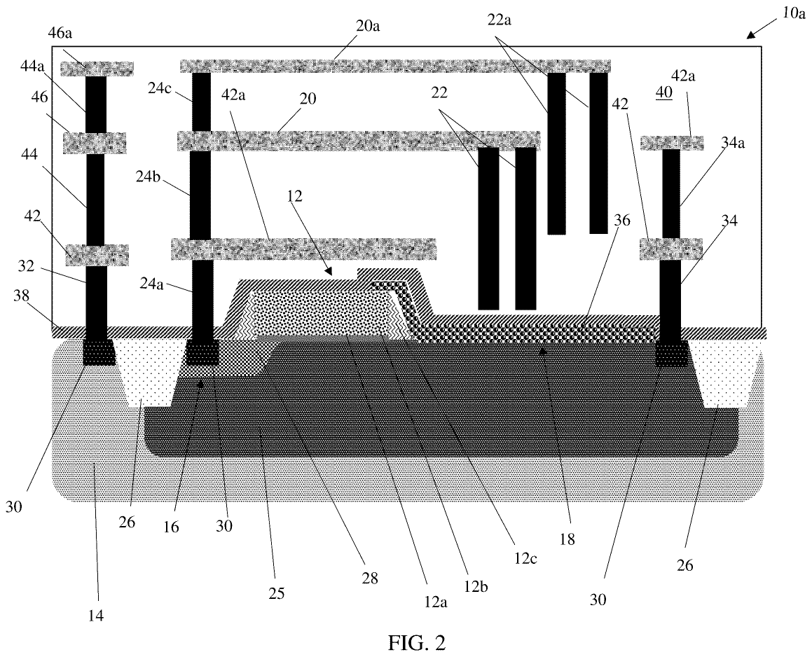

FIG. 2 shows an alternative device 10a and respective fabrication processes in accordance with additional aspects of the present disclosure. In the device 10a of FIG. 2, an additional wiring structure 20a is formed on an upper wiring level, above the field plate 20. In this embodiment, the wiring structure 20a is also a field plate that extends over the gate structure 12 and the drift region 18, and connects to the source region 16 using an additional interconnect structure 24c (connecting to the field plate 20). Moreover, the field plate 20a includes downwardly extending via structures 22a that are provided over the drift region 18, e.g., drain region. The additional extending vias 22a are, in embodiments, the same dimensions as the via structures 22 extending from the field plate 20. In this way, the via structures 22a are spaced away further from the drift region 18 than the via structures 22.

In addition, the device 10a of FIG. 2 includes wiring structure 46, 42a, extending from and connecting to the respective wiring layer 46, 42 by the interconnect structures 44a, 34a, respectively. Also, as with all of the embodiments described herein, the design parameters of the device can be tailored to the specific configuration of the field plate (with the via structure extensions) including, for example, depletion of the drift region, reduction of the surface electric field and an increase of the breakdown voltage. The remaining features of the device 10a are similar to the features of the device 10 of FIG. 1 such that no further explanation is required for a complete understanding of the present disclosure.

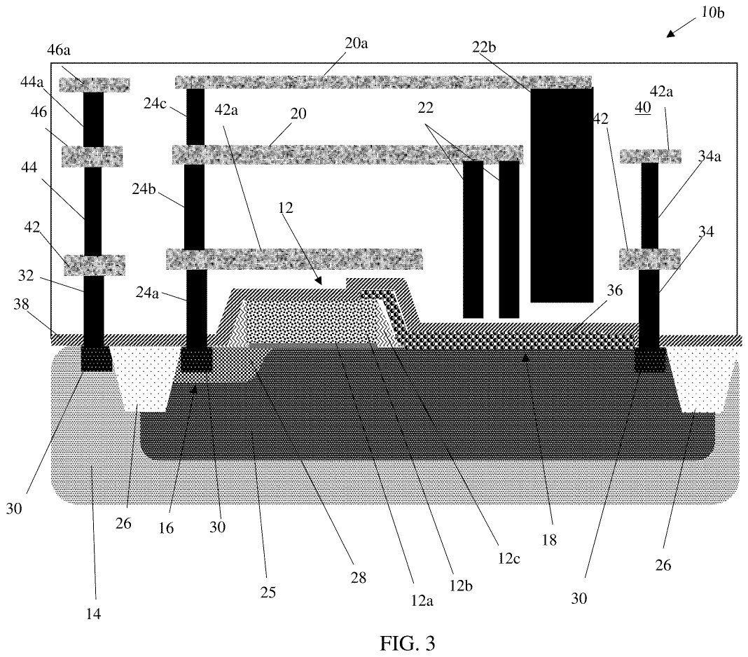

FIG. 3 shows an alternative device 10b in accordance with additional aspects of the present disclosure. In the device 10b of FIG. 3, the field plate 20a formed above the upper wiring level includes a single via structure 22b. In this embodiment, the single via structure 22b has a dimension (e.g., width or circumference and length) that is larger than the via structures 22a. In this way, the single via structure 22b may extend to the same distance (e.g., spacing) from the drift region 18 as the via structures 22a; although other spacing is contemplated herein. The remaining features of the device 10b are similar to the features of the device 10a of FIG. 2 such that no further explanation is required for a complete understanding of the present disclosure.

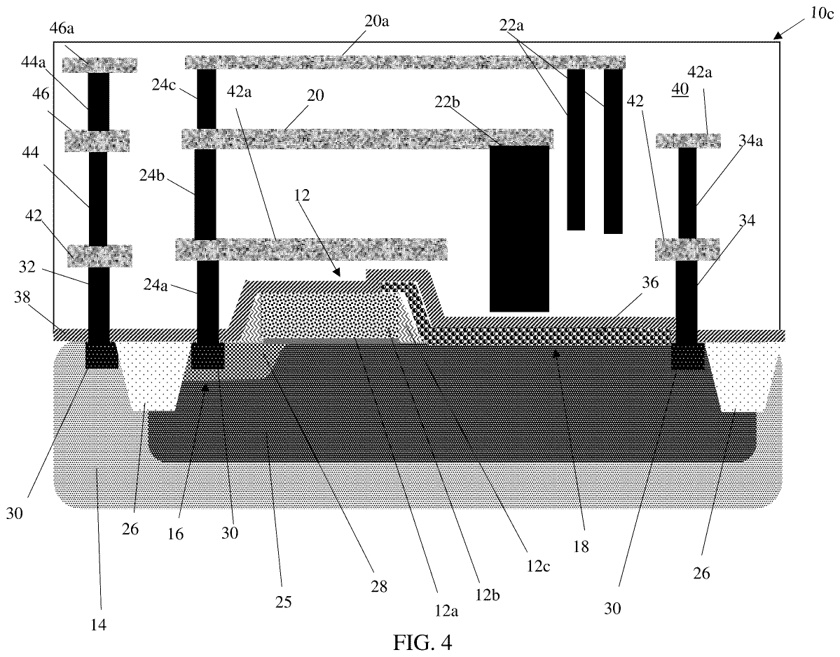

FIG. 4 shows an alternative device 10c in accordance with additional aspects of the present disclosure. In the device 10c of FIG. 4, the field plate 20 includes the single via structure 22b; whereas the single field plate 20a includes multiple via structures 22a. In this embodiment, the single via structure 22b will extend closer to the drift region 18 than the multiple via structures 22a on the upper wiring level, e.g., extending from the field plate 20a. The remaining features of the device 10c are similar to the features of the devices 10, 10a, 10b such that no further explanation is required for a complete understanding of the present disclosure.

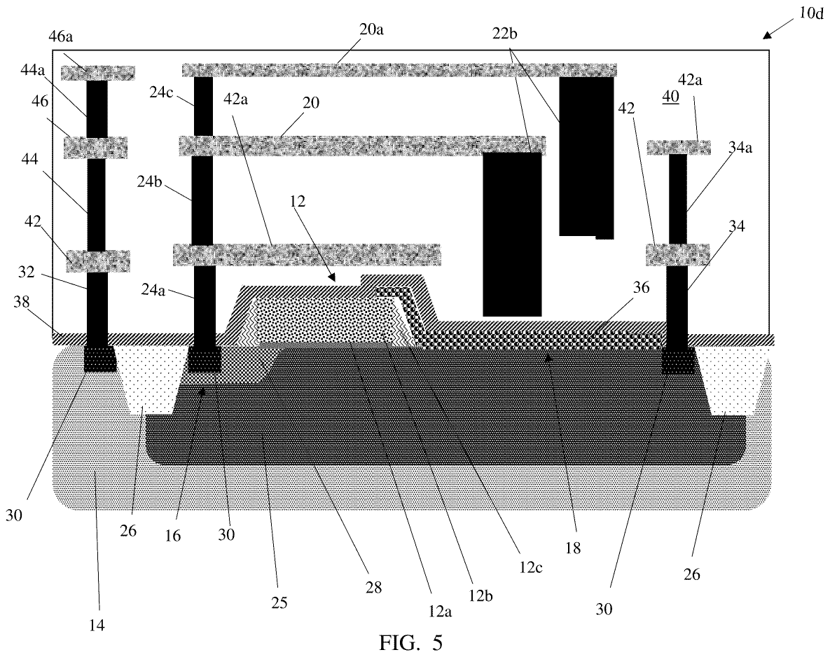

FIG. 5 shows an alternative device 10d in accordance with additional aspects of the present disclosure. In the device 10d of FIG. 5, both the field plate 20 and the field plate 20a include a single via structure 22b extending over the drift region 18. In embodiments, the single via structure 22b extending from each of the field plates 20, 20a may be the same size and shape. Also, the single via structure 22b extending from the field plate 20 will be closer to the drift region 18 than the via structure 22b extending from the field plate 20a; although other spacings and dimensions are contemplated herein. The remaining features of the device 10d are similar to the features of the devices 10, 10a, 10b, 10c such that no further explanation is required for a complete understanding of the present disclosure.

The structures can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a gate structure on a semiconductor substrate;
a source region on a first side of the gate structure;
a drain region on a second side of the gate structure; and
a field plate extending over the gate structure from the source region to the drain region, the field plate comprising at least one via structure extending toward the drain region.

2. The structure of claim 1, wherein the drain region includes a drift region and the at least one via structure extends downward over and toward the drain region.

3. The structure of claim 1, further comprising a space between the drain region and the at least one via structure.

4. The structure of claim 3, further comprising an interconnect structure contacting the source region and the field plate.

5. The structure of claim 4, wherein the at least one via structure is at least two via structures and the field plate extends above a lower field plate that extends over the gate structure.

6. The structure of claim 4, further comprising a second field plate extending over the field plate and the gate structure, the second field plate connecting to the field plate and the source region and including at least another via structure extending over the drain region.

7. The structure of claim 6, wherein the at least another via structure is a single via structure of a different dimension than the at least one via structure.

8. The structure of claim 6, wherein the at least another via structure extending from the second field plate and the at least one via structure extending from the field plate both comprise multiple via structures.

9. The structure of claim 6, wherein the at least another via structure extending from the second field plate and the at least one via structure extending from the field plate both comprise a single via structure.

10. The structure of claim 6, wherein the at least another via structure extending from the second field plate comprises at multiple via structures and the at least one via structure extending from the field plate comprise a single via structure.

11. A structure comprising:
a gate structure;
a source region on a first side of the gate structure;
a drain region on a second side of the gate structure;
a first field plate extending over the gate structure and connecting to the source region;
a second field plate over the gate structure and the first field plate, the second field plate connecting to the source region and extending to the drain region, the second field plate comprising at least one via structure extending toward the drain region; and
a spacer between the at least one via structure and the drain region.

12. The structure of claim 11, wherein the at least one via structure comprises a conductive material.

13. The structure of claim 11, wherein the at least one via structure comprises at least two via structures.

14. The structure of claim 11, further comprising a third field plate over the second field plate, the third field plate connecting to the source region, the first field plate and the second field plate, the third field plate comprising at least one via structure extending toward the drain region.

15. The structure of claim 14, wherein the at least one via structure extending from the second field plate and the at least one via structure extending from the third field plate both comprise a single field plate.

16. The structure of claim 14, wherein the at least one via structure extending from the second field plate comprises multiple via structures and the at least one via structure extending from the third field plate both comprise a single via structure.

17. The structure of claim 14, wherein the at least one via structure extending from the second field plate comprises and the at least one via structure extending from the third field plate both comprise a multiple via structures.

18. The structure of claim 14, wherein the at least one via structure extending from the second field plate comprises a single via structure and the at least one via structure extending from the third field plate both comprise multiple via structures.

19. The structure of claim 14, wherein the at least one via structure extending from the second field plate and the at least one via structure extending from the third field plate have a different spacing to the drain region.

20. A method comprising:
forming a gate structure on a semiconductor substrate;
forming a source region on a first side of the gate structure;
forming a drain region on a second side of the gate structure; and
forming a field plate extending over the gate structure from the source region to the drain region, the field plate comprising at least one via structure extending toward the drain region.
